(19) United States
(12) Patent Application Publication
(10) Pub. No.: US 2026/0082621 A1
(43) Pub. Date: Mar. 19, 2026

(54) LDMOS TRANSISTOR

(71) Applicant: Silergy Semiconductor Technology (Hangzhou) LTD, Hangzho (CN)

(72) Inventors: Hui Yu, Hangzhou (CN); Jun Cai, Hangzhou (CN)

(21) Appl. No.: 19/320,105

(22) Filed: Sep. 5, 2025

(30) Foreign Application Priority Data
Sep. 14, 2024 (CN) 202411296818.2

(51) Int. Cl. H10D 30/65; H10D 62/10; H10D 64/00

(52) U.S. Cl. CPC H10D 30/65; H10D 62/116; H10D 64/111

(57) ABSTRACT

An LDMOS transistor can include: a semiconductor region; a source region of a first doping type and a drain region of the first doping type, both being disposed in the semiconductor region; a gate dielectric layer adjacent to the source region, and being disposed on an upper surface of the semiconductor region; a voltage-blocking layer adjacent to the drain region, and being disposed on the semiconductor region; a buffer field plate between the gate dielectric layer and the voltage-blocking layer, and being disposed on the upper surface of the semiconductor region; and where a thickness of the voltage-blocking layer is greater than a thickness of the buffer field plate, and the thickness of the buffer field plate is greater than a thickness of the gate dielectric layer.

### RELATED APPLICATIONS

This application claims the benefit of Chinese Patent Application No. 202411296818.2, filed on Sep. 14, 2024, which is incorporated herein by reference in its entirety.

### FIELD OF THE INVENTION

The present invention generally relates to the field of semiconductor technology, and more particularly to semiconductor devices including LDMOS transistors.

### BACKGROUND

A switched-mode power supply (SMPS), or a “switching” power supply, can include a power stage circuit and a control circuit. When there is an input voltage, the control circuit can consider internal parameters and external load changes, and may regulate the on/off times of the switch system in the power stage circuit. Switching power supplies have a wide variety of applications in modern electronics. For example, switching power supplies can be used to drive light-emitting diode (LED) loads. Power switches can be semiconducting devices, including metal-oxide-semiconductor field-effect transistors (MOSFETs) and insulated gate bipolar transistors (IGBTs), among others. For example, laterally-diffused metal-oxide-semiconductor (LDMOS) devices are widely used in such on-off type regulators.

### BRIEF DESCRIPTION OF THE DRAWINGS

FIG. 1 is a cross-sectional view of a first example LDMOS transistor, in accordance with embodiments of the present invention.

FIG. 2 is a cross-sectional view of a second example LDMOS transistor, in accordance with embodiments of the present invention.

FIG. 3 is a cross-sectional view of a third example LDMOS transistor, in accordance with embodiments of the present invention.

FIG. 4 is a cross-sectional view of a fourth example LDMOS transistor, in accordance with embodiments of the present invention.

FIG. 5 is a cross-sectional view of a fifth example LDMOS transistor, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

Semiconductor devices are generally manufactured using two complex manufacturing processes: front-end manufacturing and back-end manufacturing. Front-end manufacturing may involve the formation of a plurality of die on the surface of a semiconductor wafer. Each die on the wafer may contain active and passive electrical components, which are electrically connected to form functional electrical circuits. Active electrical components, such as transistors and diodes, have the ability to control the flow of electrical current. Passive electrical components, such as capacitors, inductors, resistors, and transformers, create a relationship between voltage and current necessary to perform electrical circuit functions.

Passive and active components can be formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition may involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. The portion of the photoresist pattern subjected to light is removed using a solvent, exposing portions of the underlying layer to be patterned. The remainder of the photoresist may be removed, leaving behind a patterned layer. Alternatively, some types of materials can be patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface may be used to produce smaller and more densely packed active and passive components. Planarization can be used to remove material from the surface of the wafer and produce a uniformly flat surface. Planarization can involve polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

Back-end manufacturing refers to cutting or singulating the finished wafer into the individual die and then packaging the die for structural support and environmental isolation. To singulate the die, the wafer is scored and broken along non-functional regions of the wafer called saw streets or scribes. The wafer may be singulated using a laser cutting tool or saw blade. After singulation, the individual die can be mounted to a package substrate that can include pins or contact pads for interconnection with other system components. Contact pads formed over the semiconductor die can then be connected to contact pads within the package. The electrical connections can be made with solder bumps, stud bumps, conductive paste, or wire bonds, as a few examples. An encapsulant or other molding material may be deposited over the package to provide physical support and electrical isolation. The finished package can then be inserted into an electrical system and the functionality of the semiconductor device is made available to the other system components.

Laterally-diffused metal-oxide-semiconductor (LDMOS) transistors are widely used in power integrated circuits as common power devices due to their high breakdown voltage and compatibility with CMOS processes. To reduce power consumption in power stage drivers of high-frequency application terminals, it can be preferable to use thin-gate transistors with low threshold voltages. However, when such transistors operate under high voltage conditions, tunneling tends to occur in the thin gate oxide region, which may degrade the device's performance.

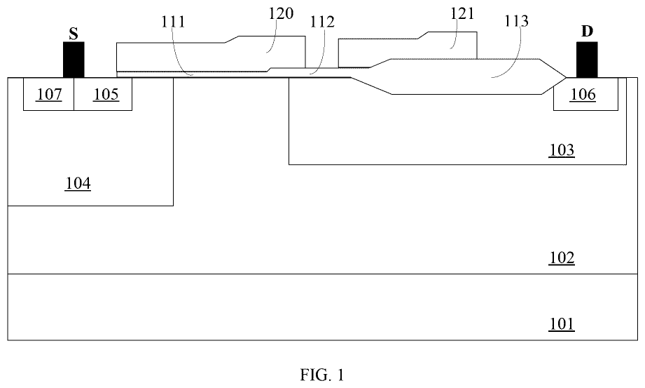

Referring now to FIG. 1, shown is a cross-sectional view of a first example LDMOS transistor, in accordance with embodiments of the present invention. In this particular, the LDMOS transistor can include semiconductor region 102, source region 105 of a first doping type and drain region 106 of the first doping type both disposed in semiconductor region 102, gate dielectric layer 111 adjacent to source region 105, voltage-blocking layer 113 adjacent to drain region 106, and buffer field plate 112 between gate dielectric layer 111 and voltage-blocking layer 113. Gate dielectric layer 111, voltage-blocking layer 113, and buffer field plate 112 can be disposed on an upper surface of semiconductor region 102.

Voltage-blocking layer 113 may be formed to protrude inwardly into semiconductor region 102. A thickness of voltage-blocking layer 113 can be greater than a thickness of buffer field plate 112, and the thickness of buffer field plate 112 may be greater than a thickness of gate dielectric layer 111. For example, a length of gate dielectric layer 111 can be less than a length of voltage-blocking layer 113, and a length of buffer field plate 112 may also be less than the length of voltage-blocking layer 113. It should be noted that the length and thickness of buffer field plate 112, as well as the length and thickness of voltage-blocking layer 113, may be adjusted as needed based on particular requirements of the applied voltage and the ultimate optimization of the specific on-resistance Rsp.

As an example, a lower surface of voltage-blocking layer 113 may be lower than a lower surface of buffer field plate 112. An upper surface of buffer field plate 112 can be higher than an upper surface of gate dielectric layer 111, and an upper surface of voltage-blocking layer 113 higher than the upper surface of buffer field plate 112. The lower surface of buffer field plate 112 and a lower surface of gate dielectric layer 111 can be coplanar or substantially coplanar. When both gate dielectric layer 111 and buffer field plate 112 are formed by a dielectric layer deposition process, the lower surfaces of buffer field plate 112 and gate dielectric layer 111 can be in the same plane (e.g., they are flush). When both are formed by a thermal oxidation process, the lower surface of buffer field plate 112 may be slightly lower than the lower surface of gate dielectric layer 111.

In particular embodiments, the thickness of buffer field plate 112 is uniform. Alternatively, the thickness of buffer field plate 112 may gradually increase in a direction from the source region toward the drain region. For example, voltage-blocking layer 113 can be shaped like a bird's beak, and may be formed by a local oxidation of silicon process. The thickness of voltage-blocking layer 113 can be uniform except for the bird's beak portion. In other examples, voltage-blocking layer 113 may be formed by a dielectric layer deposition process, in which case the lower surface of voltage-blocking layer 113 and the lower surface of buffer field plate 112 are substantially coplanar. Optionally, the thickness of voltage-blocking layer 113 may gradually increase in a direction from the source region toward the drain region.

In one example, the thickness of the gate dielectric layer can be between 0.95 nm and 9.5 nm, which may be formed synchronously with the gate oxide of gate oxide of a CMOS device. The thickness of the buffer field plate can be between 4 nm and 40 nm, and the thickness of the voltage-blocking layer may be between 25 nm and 350 nm. The buffer field plate and the voltage-blocking layer can both be formed by thermal oxidation or deposition processes.

In particular embodiments, the LDMOS transistor can also include drift region 103 of the first doping type formed in semiconductor region 102, body region 104 of a second doping type formed in semiconductor region 102, and body contact region 107 of the second doping type formed in body region 104 and adjacent to source region 105. Drain electrode D can be disposed on drain region 106, and source electrode S disposed on source region 105 and body contact region 107. Drift region 103 may be disposed at least below voltage-blocking layer 113. For example, drift region 103 can be formed to extend from drain region 106 to below buffer field plate 112.

Body region 104 may be formed to extend at least below a portion of gate dielectric layer 111. In one example, a junction depth of body region 104 can be greater than a junction depth of drift region 103. Further, when the doping types of the semiconductor region and the drift region are the same, the body region and the drift region may be arranged separately or in contact with each other. When the doping types of the semiconductor region and the drift region differ, the body region and the drift region can be arranged in contact. As an example, a junction depth of source region 105 and a junction depth of body contact region 107 may be the same.

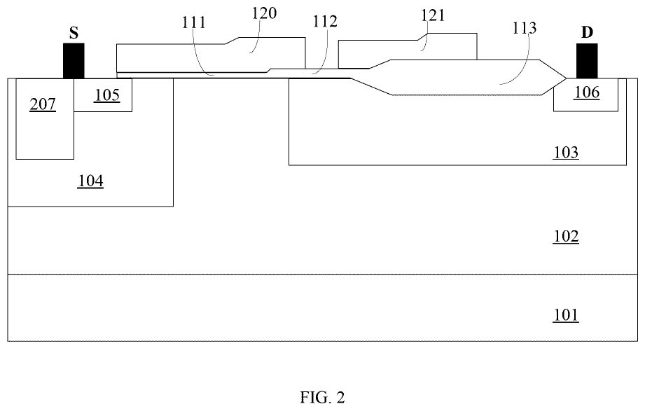

Referring now to FIG. 2, shown is a cross-sectional view of a second example LDMOS transistor, in accordance with embodiments of the present invention. In this particular example, the junction depth of body contact region 207 can be greater than the junction depth of source region 105. Further, the body contact region may surround a portion of a lower surface of source region 105, in order to reduce the base resistance of a surface parasitic transistor (e.g., formed by source region 105, body region 104, semiconductor region 102, and drift region 103), thereby reducing the impact of the surface parasitic transistor on the robustness of the LDMOS transistor.

In particular embodiments, the LDMOS transistor can also include gate conductor 120 and field-shielding conductor 121 that are arranged separately. Gate conductor 120 can be located at least on gate dielectric layer 111, and field-shielding conductor 121 located at least on voltage-blocking layer 113. As an example, gate conductor 120 may be disposed on gate dielectric layer 111 and a portion of buffer field plate 112. Field-shielding conductor 121 can be disposed on a portion of voltage-blocking layer 113 and a portion of buffer field plate 112.

In certain embodiments, gate conductor 120 may be disposed solely on gate dielectric layer 111, or may extend from gate dielectric layer 111 onto buffer field plate 112 or voltage-blocking layer 113. Field-shielding conductor 121 may be disposed solely on voltage-blocking layer 113, or may extend from voltage-blocking layer 113 onto buffer field plate 112. Gate conductor 120 and field-shielding conductor 121 can be made of polysilicon. Field-shielding conductor 121 may be of the first doping type or the second doping type. Field-shielding conductor 121 can be electrically connected to a same potential as gate conductor 120, or independently connected to a different potential.

As an example, the LDMOS transistor can also include substrate 101. The substrate can be of the second doping type, and the semiconductor region of the first doping type. Alternatively, the semiconductor region may also be of the second doping type, in which case the body region and the drift region can be arranged in contact. As such, the body region and the drift region may physically contact each other without any intervening layer, such as the semiconductor region, being interposed therebetween. Here, the semiconductor region can be a well region or an epitaxial layer. Additionally, other epitaxial layers or a buried layer may be disposed between the substrate and the semiconductor region.

In particular embodiments, the LDMOS transistor can include ultra-thin gate dielectric layer 111, which may result in a low threshold voltage for the transistor, thus reducing the energy required by low-threshold power modules in driving power integrated circuits, and increases the switching frequencies of the low-threshold power modules. Moreover, the reduced threshold voltage can increase the reverse surface channel current of the transistor, which in turn may suppress the body reverse recovery current flowing through the well and body regions. Accordingly, power loss in the power stage driver during high-frequency switching can be significantly reduced, while the reverse recovery loss of the transistor may also be minimized.

Buffer field plate 112 can be regarded as an extension of the gate dielectric layer, and may have a thickness greater than that of the gate dielectric layer, thereby reducing the electric field experienced by the gate dielectric layer near the drain region. This can help shorten the length of the gate dielectric layer, decrease the charge required to turn on the transistor, and suppress the tunneling current in the gate dielectric layer when the transistor operates under high voltage. In addition, the lower surface of the buffer field plate can be coplanar with the lower surface of the gate dielectric layer, which may result in a shorter surface current path of the transistor, which can further reduce the transistor's specific on-resistance.

Voltage-blocking layer 113 may be formed as an oxide layer thicker than buffer field plate 112, and may protrude inwardly into the semiconductor region, thereby lengthening the surface current path in the transistor's high-voltage region and enhancing its breakdown voltage capability. Voltage-blocking layer 113, together with the field shielding conductor located above it and electrically isolated from the gate electrode, as well as the drift region positioned below, can cooperatively enhance the transistor's breakdown voltage, reduce voltage coupling from the drain to the gate stage, lower voltage coupling loss, and effectively decrease the transistor's specific on-resistance.

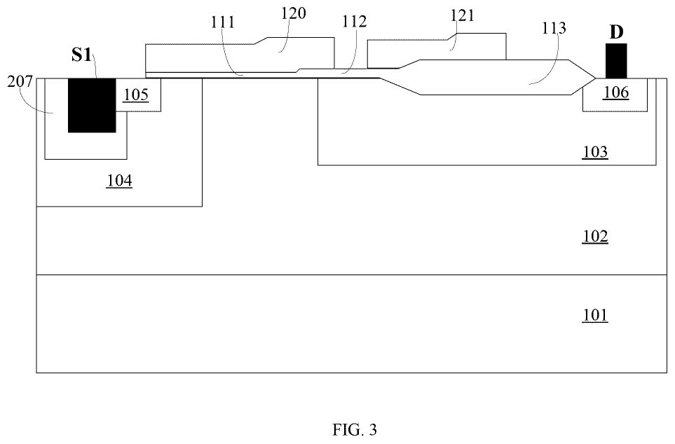

Referring now to FIG. 3, shown is a cross-sectional view of a third example LDMOS transistor, in accordance with embodiments of the present invention. In this particular example, body contact region 207 may be formed to extend downward from an upper surface of body region 104 and laterally to a position below source region 105, in order to partially surround the lower surface of source region 105. Source electrode S1 can be formed to extend from an upper surface of body contact region 207 into an interior of body contact region 207, and may be in contact with a side surface of source region 105. Further, a lower surface of the source electrode S1 can be lower than the lower surface of source region 105. For example, source electrode S1 can include a trench formed in body contact region 207 and a conductive material filled in the trench.

In certain embodiments, the arrangement of the body contact region and the source electrode may facilitate the extraction of accumulated charge in the base region of the surface parasitic transistor by the source electrode in the body contact region, thereby enhancing the high-current capability and robustness of the LDMOS transistor, as well as improving its reverse recovery performance.

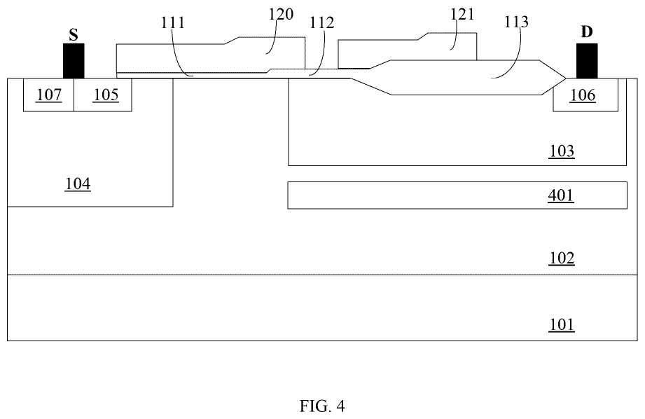

Referring now to FIG. 4, shown is a cross-sectional view of a fourth example LDMOS transistor, in accordance with embodiments of the present invention. In this particular example, reduced surface field region 401 of the second doping type can be disposed below drift region 103 of the first doping type. Reduced surface field region 401 and drift region 103 can deplete each other to reduce a surface electric field between gate and drain of the transistor and increase the breakdown voltage of the transistor. Reduced surface field region 401 may be arranged in contact with body region 104, or arranged separated from body region 104. A spacing between drift region 103 and reduced surface field region 401 can be greater than or equal to zero. Alternatively, drift region 103 and reduced surface field region 401 may be arranged side by side, or reduced surface field region 401 may surround drift region 103. The positional relationship between drift region 103 and reduced surface field region 401 may be adjusted as needed for specific application requirements.

In one example, both drift region 103 and reduced surface field region 401 can each be configured as a single layer. In other examples, drift region 103 and reduced surface field region 401 may each include multiple layers. In yet another example, drift region 103 can include multiple separately disposed first doping regions, and reduced surface field region 401 can include multiple separately disposed second doping regions. For example, the multiple separately disposed first doping regions can be arranged in a lateral direction, the multiple separately disposed second doping regions may be arranged in a lateral direction, and the second doping regions can be located below the first doping regions. For example, a corresponding second doping region may be disposed below each of the first doping regions. A spacing between adjacent first doping regions and a width of each first doping region can be set as needed for the particular application. Similarly, a spacing between adjacent second doping regions and a width of each second doping region can also be adjusted as needed for the specific application.

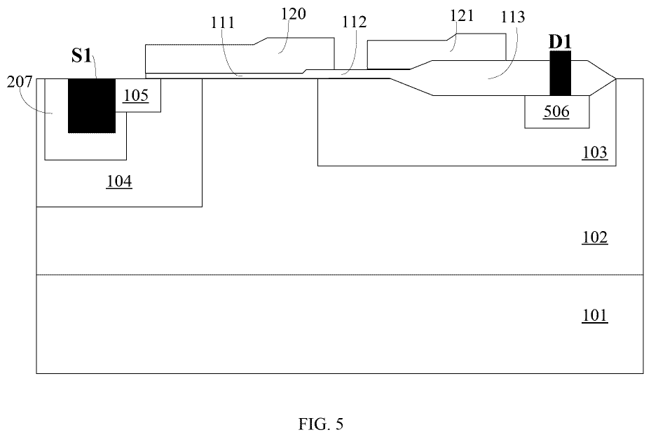

Referring now to FIG. 5, shown is a cross-sectional view of a fifth example LDMOS transistor, in accordance with embodiments of the present invention. In this particular example, drain region 506 can be located below voltage-blocking layer 113, and drain electrode D1 may extend through voltage-blocking layer 113 to be in contact with drain region 506. For example, the side edges of drain region 506 and voltage-blocking layer 113 can be aligned on a side that is farther from buffer field plate 112. Optionally, the LDMOS transistor can also include a shallow isolation trench disposed below voltage-blocking layer 113. The shallow isolation trench may be located between the source region and the drain region. As an example, the drain region may be disposed below the voltage-blocking layer, thereby eliminating the need to form a metal silicide blocking layer in the drain region to reduce the size of the LDMOS transistor.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A laterally-diffused metal-oxide-semiconductor (LDMOS) transistor, comprising:
a) a semiconductor region;
b) a source region of a first doping type and a drain region of the first doping type, both being disposed in the semiconductor region;
c) a gate dielectric layer adjacent to the source region, and being disposed on an upper surface of the semiconductor region;
d) a voltage-blocking layer adjacent to the drain region, and being disposed on the semiconductor region;
e) a buffer field plate between the gate dielectric layer and the voltage-blocking layer, and being disposed on the upper surface of the semiconductor region; and
f) wherein a thickness of the voltage-blocking layer is greater than a thickness of the buffer field plate, and the thickness of the buffer field plate is greater than a thickness of the gate dielectric layer.

2. The LDMOS transistor of claim 1, further comprising a drift region of the first doping type in the semiconductor region, wherein the drift region is disposed at least below the voltage-blocking layer.

3. The LDMOS transistor of claim 1, wherein the voltage-blocking layer is formed to protrude inwardly into the semiconductor region.

4. The LDMOS transistor of claim 1, further comprising a body region of a second doping type in the semiconductor region, wherein the body region is formed to extend at least below a portion of the gate dielectric layer.

5. The LDMOS transistor of claim 1, wherein the voltage-blocking layer comprises one or a combination of a local silicon oxide layer and a local silicon nitride layer.

6. The LDMOS transistor of claim 1, wherein the thickness of the voltage-blocking layer gradually increases in a direction from the source region toward the drain region.

7. The LDMOS transistor of claim 1, wherein the thickness of the buffer field plate gradually increases in a direction from the source region toward the drain region.

8. The LDMOS transistor of claim 1, wherein a lower surface of the buffer field plate and a lower surface of the gate dielectric layer are located on a same plane that is parallel to a direction from the source region toward the drain region.

9. The LDMOS transistor of claim 1, wherein lower surfaces of the buffer field plate and the gate dielectric layer are both higher than a lower surface of the voltage-blocking layer.

10. The LDMOS transistor of claim 1, wherein a length of the gate dielectric layer is less than a length of the voltage-blocking layer.

11. The LDMOS transistor of claim 1, wherein a length of the buffer field plate is less than a length of the voltage-blocking layer.

12. The LDMOS transistor of claim 1, wherein the thickness of the gate dielectric layer is in a range from 0.95 nm to 9.5 nm.

13. The LDMOS transistor of claim 4, further comprising a body contact region of the second doping type adjacent to the source region in the body region, and a source electrode in contact with at least the source region.

14. LDMOS transistor of claim 13, wherein a junction depth of the body contact region is greater than a junction depth of the source region.

15. LDMOS transistor of claim 14, wherein the source electrode is formed to extend from an upper surface of the body contact region into an interior of the body contact region.

16. The LDMOS transistor of claim 15, wherein a depth of the source electrode extending into the body contact region is greater than the junction depth of the source region.

17. The LDMOS transistor of claim 13, wherein the body contact region surrounds at least a portion of a lower surface of the source region.

18. The LDMOS transistor of claim 1, further comprising a gate conductor disposed at least on the gate dielectric layer.

19. The LDMOS transistor of claim 1, further comprising a field shielding conductor disposed at least on the voltage-blocking layer.

20. The LDMOS transistor of claim 1, further comprising a drain electrode formed to extend through the voltage-blocking layer to the drain region located below the voltage-blocking layer.
